(19) United States
(12) Patent Application Publication
(10) Pub. No.: US 2005/0067651 A1
(43) Pub. Date: Mar. 31, 2005

(54) Nonvolatile memory cell employing a plurality of dielectric nanoclusters and method of fabricating the same

(76) Inventors: Ki-Chul Kim, Gyeonggi-do (KR); Byou-Ree Lim, Gyeonggi-do (KR); Sang-Su Kim, Gyeonggi-do (KR); Byoung-Jin Lee, Seoul (KR); In-Wook Cho, Gyeonggi-do (KR)

Correspondence Address: MARGER JOHNSON & MCCOLLOM, P.C., 1030 SW MORRISON STREET, PORTLAND, OR, 97205, US

(21) Appl. No.: 10/944,382

(22) Filed: Sep. 16, 2004

(30) Foreign Application Priority Data
Sep. 26, 2003 (KR) 2003-66939

(51) Int. Cl. H01L 29/76

(52) U.S. Cl. 257/314

(57) ABSTRACT

A nonvolatile memory cell employing a plurality of dielectric nanoclusters and a method of fabricating the same are disclosed. In one embodiment, the nonvolatile memory cell comprises a semiconductor substrate having a channel region. A control gate is disposed above the channel region. A control gate dielectric layer is disposed between the channel region and the control gate. A plurality of dielectric nanoclusters are disposed between the channel region and the control gate dielectric layer. Each nanocluster may be separated from adjacent nanoclusters by the control gate dielectric layer. A tunnel oxide layer is disposed between the plurality of dielectric nanoclusters and the channel region. Further, a source and a drain are formed in the semiconductor substrate.

### CROSS-REFERENCE TO RELATED APPLICATION

This application claims the benefit of Korean Patent Application No. 2003-66939, filed on Sep. 26, 2003, the disclosure of which is hereby incorporated herein by reference in its entirety.

### BACKGROUND OF THE INVENTION

1. Field of the Invention

This disclosure relates to a nonvolatile memory cell and method of fabricating the same and, more particularly, to a nonvolatile memory cell employing a plurality of dielectric nanoclusters and method of fabricating the same.

2. Description of the Related Art

Nonvolatile memory devices are desired because they retain data even if power is not supplied to them. These devices comprise flash memory and have been widely used in file systems, memory cards, and portable devices, etc.

The nonvolatile memory device may be classified as having a stacked gate structure, a notched gate structure or a nanodot gate structure. The stacked gate structure is characterized in that a tunnel oxide layer, a floating gate, a control gate dielectric layer and a control gate are sequentially stacked on a channel region of a semiconductor substrate.

The nonvolatile memory cell having the stacked gate structure is programmed through hot electron injection where a high voltage is applied to the control gate and a potential difference between a source and a drain is generated. As a result, hot electrons are generated at the channel region near the drain, and the hot electrons go over the energy barrier of the tunnel oxide layer and are injected into the floating gate. When the electrons are injected into the floating gate, a threshold voltage required to active the transistor is increased.

During a read operation the state of the memory cell is tested by applying a small voltage to the control gate. The voltage is enough to cause the transistor to operate at a lower threshold voltage, i.e. when the floating gate does not contain electrons. The applied voltage, however, is lower than the increased voltage caused by a floating gate containing electrons. Therefore, when a voltage smaller than the increased threshold voltage is applied to the control gate, there is no current flowing in the programmed cell if the floating gate contains electrons. By examining whether current flows through the transistor one can tell the state of the floating gate, and thus whether the memory cell represents a 1 or 0.

The information of the nonvolatile memory cell having the stacked gate structure may be erased by removing electrons from the floating gate by means of Fowler-Nordheim tunneling (hereinafter, referred to as F-N tunneling). During F-N tunneling a high voltage is applied to the source and 0 V is applied to the control gate and the substrate. As a result, a strong electric field is generated between the source region and the floating gate, thereby inducing the F-N tunneling.

A nonvolatile memory cell with the stacked gate structure is not a perfect solution, partly due to problems of electron retention. For the nonvolatile memory cell to maintain the programmed state, the electrons injected into the floating gate must be retained. However, when there are defects such as pinholes in the tunnel dielectric layer, the electrons injected into the floating gate escape through these defects. Unfortunately, a single pinhole can cause the majority of electrons in the floating gate to escape since the floating gate is formed of the conductive layer and the electrons can move freely within the floating gate.

Another problem with the stacked gate structure is overerasing. When the electrons injected into the floating gate are removed too many times, overerasing may occur.

The nanodot gate structure has been developed as a partial solution to the electron retention and over erasing problems inherent in the stacked gate structure. Methods of fabricating a semiconductor device having the nanodot gate structure are disclosed by Sugiyama, etc. in U.S. Pat. No. 6,060,743 entitled “Semiconductor memory device having multilayer group IV nanocrystal quantum dot floating gate and method of manufacturing the same” and by Ueda, etc. in U.S. Pat. No. 6,090,666 entitled “Method for fabricating semiconductor nanocrystal and semiconductor memory device using the semiconductor nanocrystal”.

The accepted methods generally form a line of nanodots and use these in place of a floating gate. In these methods, the nanodots are formed of a semiconductor, such as Si or Ge, and are separated from each other by a dielectric layer. During programming, electrons are injected into the nanodots, and since the nanodots are separated with each other electron movement among the nanodots is restricted. Therefore, if a single pinhole was generated in the tunnel dielectric layer only electrons from the nanodots near the single pinhole are likely to escape and the floating gate will generally remain programmed. Therefore, the nanodot structure enhances the charge retention capability of the floating gate.

Further, since the electron movement among the nanodots is restricted, the overerase problem is also mitigated. When electrons injected into the floating gate are removed near the source by F-N tunneling, the overerase occurs only in the nanodots near the source instead of in the entire floating gate.

It is desirable to form nanodots from a conductive material instead of a semiconductor for ease of manufacturing and other reasons. However, forming nanodots of conductive material creates problems. For example, when defects are generated in the dielectric layer near the nanodots, such as in the tunnel dielectric layer, conventional conductive nanodots easily lose injected electrons through current leakage. When the defects are generated in a portion of the tunnel dielectric layer, the leakage current is generated in a portion of the nanodots, and the nanodots develop non-uniform charge spatial distribution. To compensate for the charge loss due to the leakage current, an additional circuit may be formed, but this accompanies an increase in a chip area.

Further, when nanodots are formed of conductive material, the overerase problem still occurs. This overerase weakens a programming characteristic of the memory cell, thereby inducing the cell failure.

Embodiments of the invention address these and other limitations in the prior art.

### SUMMARY OF THE INVENTION

It is, therefore, a feature of the present invention to provide a nonvolatile memory cell capable of preventing a leakage current due to defects generated in a tunnel dielectric layer or a control gate dielectric layer and minimizing the overerase.

It is another feature of the present invention to provide a method of fabricating the nonvolatile memory cell.

In one embodiment of the present invention, a nonvolatile memory cell employs a plurality of dielectric nanoclusters. The nonvolatile memory cell comprises a semiconductor substrate having a channel region. A control gate is disposed above the channel region. A control gate dielectric layer is disposed between the channel region and the control gate. A plurality of dielectric nanoclusters is disposed between the channel region and the control gate dielectric layer. Each dielectric nanocluster may be separated from adjacent nanoclustors by the control gate dielectric layer. Further, a tunnel dielectric layer is disposed between the plurality of dielectric nanoclusters and the channel region. A source and a drain are located in the semiconductor substrate being separated by the channel region and the control gate.

Each of the plurality of the nanoclusters may be a high-k dielectric nanocluster. The high-k dielectric nanocluster may be a nitride, such as silicon nitride (SiN) or boron nitride (BN), or a high-k dielectric material, such as silicon carbide (SiC), Si-rich oxide, alumina (Al₂O₃), zirconium oxide (ZrO₂), hafnium oxide (HfO₂), or lanthanum oxide (La₂O₃). Or, the high-k dielectric nanocluster may be formed of a mixture of at least two materials chosen from SiN, BN, SiC, Si-rich oxide, Al₂O₃, ZrO₂, HfO₂, or La₂O₃, or a stacked layer of at least two layers chosen from the above group.

During the program operation, electrons are injected into the plurality of dielectric nanoclusters. Since the nanoclusters are dielectric materials, they have a good performance in electron retention. Therefore, even though the defects are generated in the tunnel dielectric layer or the control gate dielectric layer near the nanoclusters, the leakage current may be prevented. Further, since the nanoclusters are dielectric materials, the overerase may be minimized during the erase operation.

Preferably, conductive nanodots may be placed on each of the plurality of dielectric nanoclusters. The conductive nanodots may be Si, Ge or metal nanodots. The electrons may also be injected into the conductive nanodots during programming. Even though the electrons are injected into the conductive nanodots and defects may be generated in the tunnel dielectric layer, leakage current will be prevented by the dielectric nanoclusters.

The tunnel dielectric layers may be connected with each other to cover the entire channel region.

In another embodiment, the present invention provides a method of fabricating a nonvolatile memory cell employing a plurality of dielectric nanoclusters. The method comprises sequentially forming a tunnel dielectric layer and a trap dielectric layer on a semiconductor substrate. Semiconductor or metal nanodots are formed on the trap dielectric layer. Using the nanodots as an etch mask, the trap dielectric layer is etched to form dielectric nanoclusters. A control gate dielectric layer and a control gate conductive layer are formed on the semiconductor substrate having the dielectric nanoclusters. The control gate conductive layer, the control gate dielectric layer, the nanodots and the nanoclusters are patterned using photolithography and etching processes to form a gate pattern on a predetermined region of the semiconductor substrate. Impurity ions are injected using the control gate as an ion injection mask to form a source and a drain.

Preferably, the method further comprises, after etching the trap dielectric layer, continuously etching the tunnel dielectric layer using the nanodots as an etch mask to expose the semiconductor substrate. Accordingly, the tunnel dielectric layer is confined under the dielectric nanoclusters, and an upper portion of the exposed semiconductor substrate is covered with the control gate dielectric layer.

Preferably, the method may further comprise oxidizing the nanodots. When the nanodots are oxidized, an etching selectivity ratio of the control gate dielectric layer to the nanodots may be reduced, thereby making it easy to etch and remove the nanodots while forming the gate pattern.

Preferably, forming the source and drain may comprise extension regions and halos by injecting impurity ions using the control gate as an ion injection mask on the semiconductor substrate having the gate pattern. Spacers are formed to cover sidewalls of the gate pattern, and high density impurity ions are injected using the control gate and the spacers as the ion injection mask,

The present invention will be better understood from the following detailed description of the exemplary embodiment thereof taken in conjunction with the accompanying drawings, and its scope will be pointed out in the appended claims.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIG. 1 is a layout of nonvolatile memory cells according to a preferred embodiment of the present invention; and

FIGS. 2 to 8 are cross sectional views for illustrating a method of fabricating a nonvolatile memory cell according to a preferred embodiment of the present invention taken along the line I-I of FIG. 1.

### DETAILED DESCRIPTION OF THE PREFERRED EMBODIMENTS

Embodiments of the present invention will now be described more fully hereinafter with reference to the accompanying drawings, in which preferred embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. Like numbers refer to like elements throughout the specification. It will be understood that when an element such as a layer, region or substrate is referred to as being “on” or “onto” another element, it can be directly on the other element or intervening elements may also be present. Additionally, when the layer, region or substrate could be partially within or partially embedded in another element.

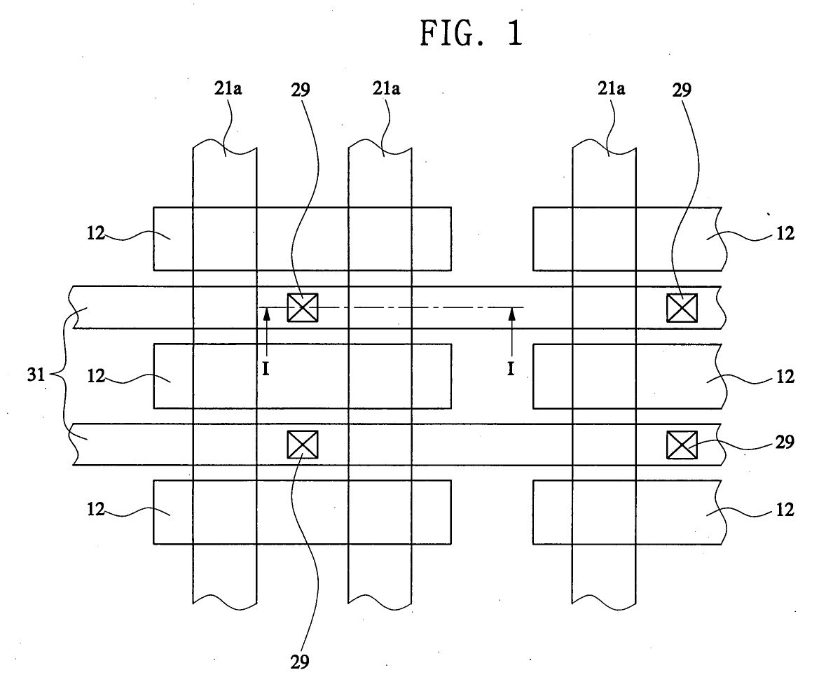

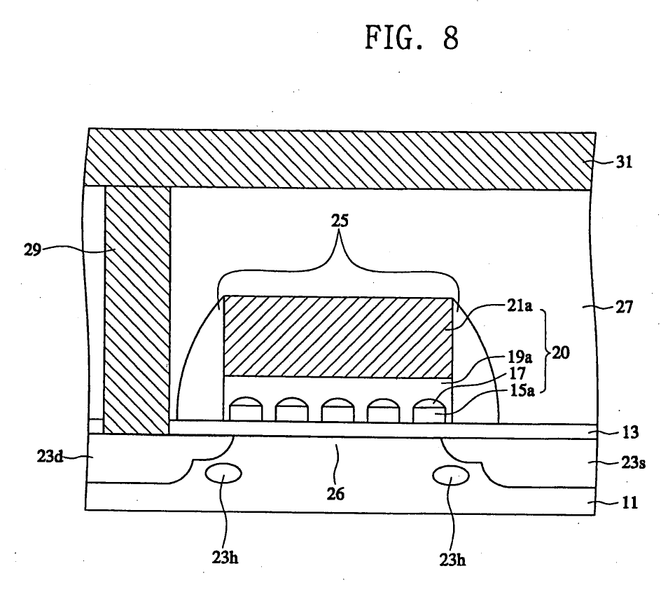

FIG. 1 is a layout of nonvolatile memory cells according to an embodiment of the present invention, and FIG. 8 is a cross sectional view of a nonvolatile memory cell taken along line I-I of FIG. 1.

Referring to FIGS. 1 and 8, isolation regions 12 are arranged within a cell region of semiconductor substrate 11 at substantially uniform intervals. The semiconductor substrate 11 may be a semiconductor substrate such as silicon substrate or silicon-on-insulator (SOI) substrate. The region excluding the device isolation regions 12 is defined as an active region. The active region includes a channel region 25, and a source 23s and a drain 23d separated by the channel region 25. Further, halos 23h may be placed near the source 23s and/or the drain 23d.

Control gates 21a extend across the channel region 25. The control gates 21a are formed of a conductive layer, such as a doped-polysilicon layer.

A control gate dielectric layer pattern 19a is interposed between the control gates 21a and the channel region 25. The control gate dielectric layer pattern 19a is a dielectric layer formed of a material such as SiO₂ or SiON.

A plurality of dielectric nanoclusters 15a are interposed between the control gate dielectric layer pattern 19a and the channel region 25. The dielectric nanoclusters 15a are separated by the control gate dielectric layer pattern 19a.

Preferably, the dielectric nanoclusters 15a may be formed of a dielectric material, e.g., a nitride, such as SiN or BN, or a high-k dielectric material, such as SiC, Si-rich oxide, Al₂O₃, ZrO₂, HfO₂, and La₂O₃. The nitride or the high-k dielectric material has a good capability in trapping electrons. Further, each of the dielectric nanoclusters 15a may be a nanocluster that comprises a mixture or composite layer of at least two materials chosen from SiN, BN, SiC, Si-rich oxide, Al₂O₃, ZrO₂, HfO₂, or La₂O₃ , or a nanocluster that comprise stacked layers of at least two material layers formed of a material chosen from the above group.

A nanodot 17 may be placed on the dielectric nanoclusters 15a. The nanodot 17 may be formed of either a semiconductor material, such as Si or Ge, or a metal material, or oxides thereof.

A tunnel dielectric layer 13 is interposed between the dielectric nanoclusters 15a and the channel region 25. The tunnel dielectric layer 13 may be confined under the dielectric nanoclusters 15a, and the resulting empty spaces within the tunnel dielectric layer 13 may be filled with the control gate dielectric layer 19a. Further, the tunnel dielectric layer 13 may be connected with each other to cover substantially the entire surface of the channel region 25 as shown in FIG. 8.

The tunnel dielectric layer 13 may be formed of SiO₂, SiON, La₂O₃, or Al₂O₃, and a stacked or mixed layer of at least two among these.

Spacers 25 may cover sidewalls of the control gate 21a and the control gate dielectric layer 19a.

Bit lines 31 cross over the control gates 21a. The bit lines 31 may be electrically connected to the drains 23d through contact plugs 29. The bit lines 31 and the control gates 21a are electrically insulated by an interlayer insulating layer 27.

A common electrode (not shown) electrically connected to the source 23s through another contact plug (not shown) may be placed on the same plane with the bit lines 31.

A method of fabricating a nonvolatile memory cell according to an embodiment of the present invention is now described, and operations, such as program, read and erase, of the memory cell will be described.

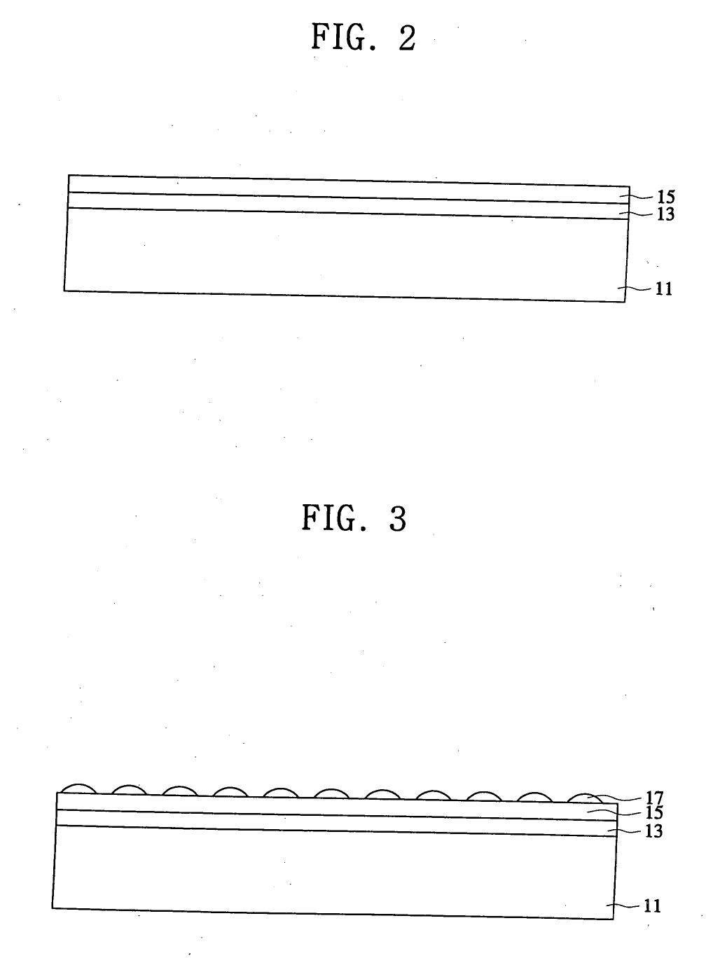

FIGS. 2 to 8 are cross-sectional views illustrating a method of fabricating a nonvolatile memory cell taken along line I-I of FIG. 1.

Referring to FIGS. 1 and 2, isolation layers 12 are formed in the semiconductor substrate 11. The isolation layers 12 may be formed using conventional isolation techniques such as local oxidation of silicon (LOCOS) technology or shallow trench isolation (STI) technology.

A tunnel dielectric layer 13 is formed on the semiconductor substrate 11 having the isolation layers 12. Preferably, the tunnel dielectric layer 13 may be formed of a dielectric material such as SiO₂, SiON, La₂O₃, ZrO₂, or Al₂O₃, and may be formed of a stacked or composite layer of at least two among them. The tunnel dielectric layer 13 may be formed of SiO₂.

A trap dielectric layer 15 is formed on the semiconductor substrate 11 having the tunnel dielectric layer 13. The trap dielectric layer 15 is formed of a dielectric layer that has a good charge-trapping capability. Generally, a high-k dielectric layer has a good capability in trapping the charges. Preferably, the trap dielectric layer 15 may be formed of a nitride, such as SiN or BN, or formed of a high-k dielectric layer, such as SiC, Si-rich oxide, Al₂O₃, ZrO₂, HfO₂, and La₂O₃. Alternatively, the trap dielectric layer 15 may be formed of a layer comprising a mixture of at least two materials chosen from SiC, Si-rich oxide, Al₂O₃, ZrO₂, HfO₂, or La₂O₃, and may be formed by stacking at least two layers formed of a material chosen from the above group.

Referring to FIGS. 1 and 3, the nanodots 17 are formed on the trap dielectric layer 15 to be separated from each other. The nanodots 17 may be formed of a semiconductor material, such as Si or Ge, or a metal material. The nanodots 17 may be formed using a well-known method. That is, the nanodots 17 may be formed by a chemical vapor deposition (CVD), or an ultra high vacuum CVD (UHVCVD), and may be formed by crystallizing the deposited layer at high temperature after depositing an amorphous or polycrystalline layer.

Preferably, if the oxide of the nanodots 17 has an etching selectivity to the trap dielectric layer 15, the nanodots 17 can be oxidized.

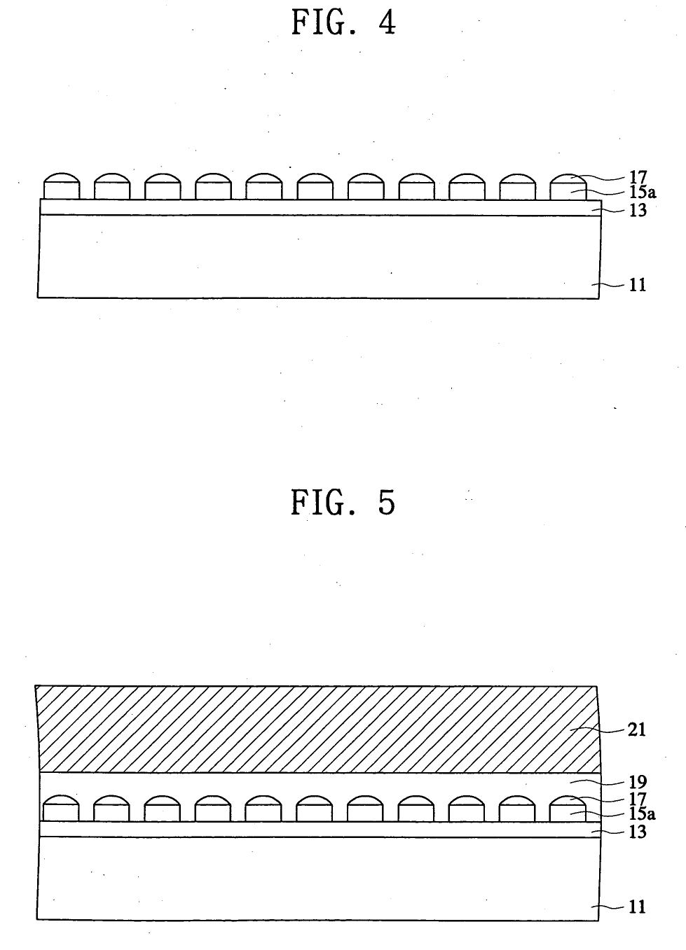

Referring to FIGS. 1 and 4, the trap dielectric layer 15 is etched, using the nanodots 17 as an etch mask, to form a plurality of dielectric nanoclusters 15a. In one embodiment, the tunnel dielectric layer 13 may be etched along with the trap dielectric layer 15 until the upper surface of the semiconductor substrate 11 is exposed.

When the nanodots 17 are not oxidized before etching the trap dielectric layer 15, the nanodots 17 may be oxidized after the plurality of dielectric nanoclusters 15a are formed.

Referring to FIGS. 1 and 5, a control gate dielectric layer 19 and a control gate conductive layer 21 are sequentially formed on the semiconductor substrate 11 having the plurality of dielectric nanoclusters 15a.

The control gate dielectric layer 19 may be formed of a dielectric layer, such as SiO₂ or SiON. Further, the control gate dielectric layer 19 may be formed using in-situ steam generation (ISSG), wet oxidation, dry oxidation, CVD or atomic layer deposition (ALD) techniques.

The control gate conductive layer 21 may be formed of at least one material layer formed of a material selected from the group of Poly-Si, W, SiGe, SiGeC, Mo, MoSi₂, Ti, TiSi₂, and TiN, and preferably, of Poly-Si layer.

A hard mask layer (not shown) may be formed on the control gate conductive layer 21 in order to pattern the control gate conductive layer 21.

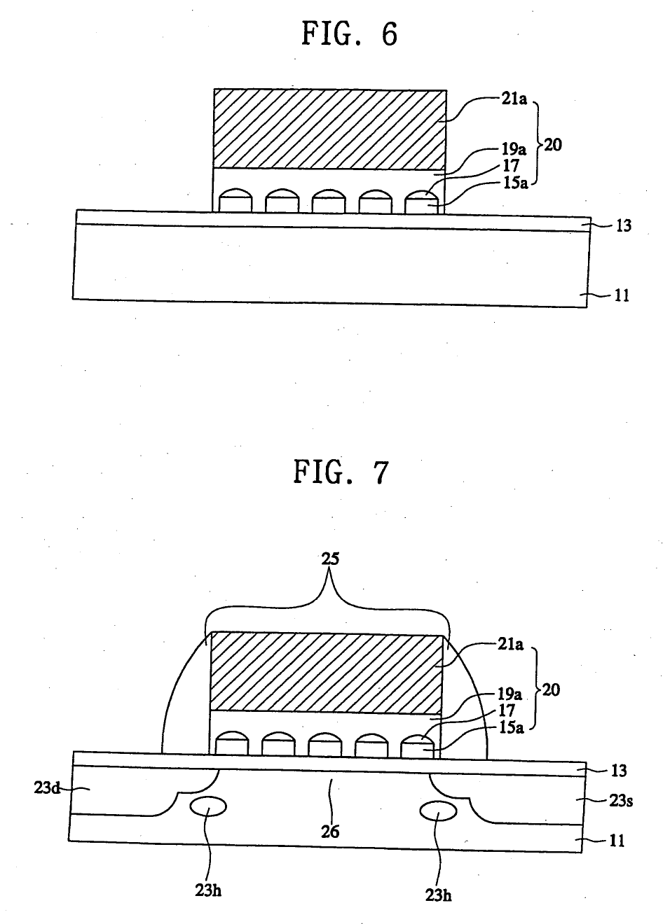

Referring to FIGS. 1 and 6, the control gate conductive layer 21, the control gate dielectric layer 19, the nanodots 17, and the plurality of dielectric nanoclusters are sequentially patterned, using photolithography and etching processes, to form a gate pattern 20 crossing over an active region of the semiconductor substrate 11. The gate pattern 20 comprises the dielectric nanoclusters 15a, the nanodots 17 located on the nanoclusters 15a, and the control gate dielectric layer pattern 19a and the control gate 21a, which are sequentially stacked. The dielectric nanoclusters 15a may be separated by the control gate dielectric layer pattern 19a.

If the nanodots 17 were oxidized, the etching selectivity of the control gate dielectric layer 19 to the nanodots 17would be reduced. Thus, it is easy to remove the nanodots 17 by etching while forming the gate pattern 20.

Preferably, while forming the gate pattern 20, the tunnel dielectric layer 13 may be etched to expose a portion of the semiconductor substrate 11.

Referring to FIGS. 1 and 7, after the gate pattern 20 is formed, impurity ions are injected into the semiconductor substrate 11 using the control gate 21a as an ion injection mask to form the source 23s and the drain 23d.

The source 23s and the drain 23d may be formed using typical extension ion implantation and high-density impurity ion implantation processes. Preferably, N-type impurity ions may be injected using the control gate 21a as ion injection mask to form extension regions at the surface of the semiconductor substrate 11 having the gate pattern 20.

After or before forming the extension regions, P-type impurity ions are injected to form halos 23h. The halos 23h may be formed near the source 23s and/or the drain 23d.

A spacer layer is formed on the semiconductor substrate 11 having the extension regions and the halos 23h. The spacer layer may be formed of a silicon oxide layer or a silicon nitride layer. Next, the spacer layer is etched back to form spacers 25 covering sidewalls of the gate pattern 20. Here, portions of the tunnel oxide layer 13 may also be removed to expose the upper surface of the semiconductor substrate 11.

N-type high density impurity ions are injected using the spacers 25 and the control gate 21 as an ion injection mask to form source/drain 23s and 23d.

Referring to FIGS. 1 and 8, the interlayer insulating layer 27 is formed on the semiconductor substrate 11 having the source/drain 23s and 23d. The interlayer insulating layer 27 is patterned to form a contact hole exposing the drain 23d.

Next, the bit line 31 is formed to be electrically connected to the drain region 23d through the contact hole. Before forming the bit line 31, the contact plug 29 that fills the contact hole may be formed.

Operations for program, read and erase of the nonvolatile memory cell according to the preferred embodiment of the present invention will now be described with reference to FIG. 8.

A program operation may be performed by applying a voltage to the control gate 21a and the source region 23s, and grounding the drain region 23d. Accordingly, hot electrons are generated near the source 23s.

The hot electrons go over an energy barrier of the tunnel dielectric layer 13 and are injected into the plurality of dielectric nanoclusters 15a near the source 23s. As the hot electrons are injected into the plurality of dielectric nanoclusters 15a, a threshold voltage Vth of the nonvolatile memory cell is increased. As a result, information is stored into the nonvolatile memory cell. Since the dielectric nanoclusters 15a are separated by the control gate dielectric layer 19a, the electrons injected into any one of dielectric nanoclusters may not be moved into other dielectric nanoclusters.

Meanwhile, the plurality of dielectric nanoclusters 15a is formed of a non-conductive material. Therefore, even though defects exist in the tunnel dielectric layer 13 or the control gate dielectric layer 19a near the dielectric nanoclusters 15a, the leakage current is prevented.

Further, the program operation may be performed by grounding the source 23s and the drain 23d and applying the voltage to the control gate 21a and the semiconductor substrate 11 to induce F-N tunneling. Here, electrons are uniformly injected into the plurality of dielectric nanoclusters 15a by means of the F-N tunneling. Also, in this case, even though the defects exist in the tunnel dielectric layer 13 or the control gate dielectric layer 19a, the leakage current is prevented.

A read operation is performed by applying the voltage to the control gate 21a and the drain 23d, and grounding the source 23s. Here, a gate voltage Vg applied to the control gate is lower than the threshold voltage at the time the electrons are injected into the plurality of dielectric nanoclusters 15a. Therefore, in a cell where the hot electrons are injected into the dielectric nanoclusters 15a, a channel current does not flow. Therefore, information 0 is obtained in the cell where the hot electrons are injected into the dielectric nanoclusters 15a.

In a cell where the hot electrons are not injected into the dielectric nanoclusters 15a, the channel turns on by the gate voltage Vg, thereby allowing current flow. Therefore, in the cell where the hot electrons are not injected into the dielectric nanoclusters 15a, information 1 is obtained.

An erase operation may be performed using hot hole injections. That is, by applying a negative voltage to the control gate 21a, hot holes are generated near the source 23s. The hot holes go over the energy barrier of the tunnel dielectric layer 13 by the voltage of the control gate 21a and are injected into the dielectric nanoclusters 15a near the source. The hot holes injected into the dielectric nanoclusters 15a get rid of the electrons in the dielectric nanoclusters 15a.

Since the dielectric nanoclusters 15 are separated with each other and formed of the non-conductive material, the overerase may be minimized. Further, since the hot electrons are restrictively injected and maintained in the dielectric nanoclusters 15a near the source 23s during the program operation, the erase operation using the hot hole injection is enough to perform only for the dielectric nanoclusters 15a near the source.

When the electrons are uniformly injected into the plurality of dielectric nanoclusters 15a by F-N tunneling, the erase operation may be performed using F-N tunneling. That is, the control gate 21a is applied to the negative voltage, and the semiconductor substrate 11 is applied to the positive voltage. Accordingly, the electrons injected into the dielectric nanoclusters 15a are erased by tunneling.

According to the present invention, by employing the dielectric nanoclusters to retain the electrons, the leakage current due to the defects generated in the tunnel dielectric layer or the control gate dielectric layer may be prevented, and a nonvolatile memory cell capable of minimizing the overerase during the erase operation may be provided. Further, the nonvolatile memory cell employing the dielectric nanoclusters may be manufactured.

While the present invention has been particularly shown and described with reference to preferred embodiments thereof, it will be understood by those of ordinary skill in the art that various changes in form and details may be made therein without departing from the spirit and scope of the present invention as defined by the following claims.

1. A nonvolatile memory cell comprising:
a semiconductor substrate having a channel region;
a control gate disposed above the channel region;
a control gate dielectric layer disposed between the channel region and the control gate;
a plurality of dielectric nanoclusters disposed between the channel region and the control gate dielectric layer, each dielectric nanocluster being separated from adjacent nanoclusters by the control gate dielectric layer;
a tunnel dielectric layer disposed between the plurality of dielectric nanoclusters and the channel region; and
a source and a drain located in the semiconductor substrate and separated by the channel region.

2. The nonvolatile memory cell of claim 1, wherein the plurality of dielectric nanoclusters comprise a high-k dielectric nanocluster.

3. The nonvolatile memory cell of claim 2, wherein the high-k dielectric nanocluster comprises a SiN or BN nanocluster.

4. The nonvolatile memory cell of claim 3, wherein the tunnel dielectric layer is at least one layer formed of a material selected from the group consisting of SiO₂, SiON, Al₂O₃, ZrO₂, and La₂O₃, or is a layer comprising a mixture of at least two materials chosen from the above group.

5. The nonvolatile memory cell of claim 2, wherein the high-k dielectric nanocluster is a nanocluster formed of a material selected from the group consisting of SiC, Si-rich oxide, Al₂O₃, ZrO₂, La₂O₃, and combinations thereof.

6. The nonvolatile memory cell of claim 2, wherein the high-k dielectric nanocluster is a nanocluster comprising a mixture of at least two materials chosen from SiN, BN, SiC, Si-rich oxide, Al₂O₃, ZrO₂, or La₂O₃.

7. The nonvolatile memory cell of claim 2, wherein the high-k dielectric nanocluster is a nanocluster stacked with at least two layers comprising a material chosen from SiN, BN, SiC, Si-rich oxide, Al₂O₃, ZrO₂, HfO₂, or La₂O₃.

8. The nonvolatile memory cell of claim 1, further comprising conductive nanodots located on the plurality of nanoclusters.

9. The nonvolatile memory cell of claim 8, wherein the conductive nanodots are Si, Ge or metal nanodots.

10. The nonvolatile memory cell of claim 1, wherein the tunnel dielectric layer covers substantially an entire surface of the channel region.

11. A method of fabricating a nonvolatile memory cell comprising:
forming a tunnel dielectric layer above a semiconductor substrate;
forming a trap dielectric layer on the tunnel dielectric layer;
etching the trap dielectric layer to form dielectric nanoclusters;
sequentially forming a control gate dielectric layer and a control gate conductive layer overlying the dielectric nanoclusters;
sequentially patterning the control gate conductive layer, the control gate dielectric layer, and the nanoclusters to form a gate pattern on a region of the semiconductor substrate; and
forming a source and a drain in the semiconductor substrate adjacent the gate pattern.

12. The method of claim 11, wherein the trap dielectric layer is formed of a high-k dielectric layer.

13. The method of claim 12, wherein the high-k dielectric layer is a SiN or BN layer.

14. The method of claim 13, wherein the tunnel dielectric layer is at least one layer selected from the group consisting of SiO₂, SiON, Al₂O₃, ZrO₂, and La₂O₃, or is a layer comprising a mixture of at least two materials chosen from the above group.

15. The method of claim 12, wherein the high-k dielectric layer is a layer formed of a material selected from the group consisting of SiC, Si-rich oxide, Al₂O₃, ZrO₂, and La₂O₃.

16. The method of claim 12, wherein the high-k dielectric layer is a layer comprising a mixture of at least two materials chosen from SiN, BN, SiC, Si-rich oxide, Al₂O₃, ZrO₂, HfO₂, or La₂O₃.

17. The method of claim 12, wherein the high-k dielectric layer is formed of at least two layers comprising a material selected from the group consisting of SiN, BN, SiC, Si-rich oxide, Al₂O₃, ZrO₂, HfO₂, and La₂O₃.

18. The method of claim 11, wherein etching the trap dielectric layer further comprises partially etching the tunnel dielectric layer.

19. The method of claim 11, wherein forming the source and the drain comprises:
injecting ions, using the control gate as an ion injection mask, to form extension regions and halos on the semiconductor substrate having the gate pattern;
forming spacers on sidewalls of the gate pattern; and
injecting the ions, using the control gate and the spacers as an ion injection mask.

20. The method of claim 11, further comprising forming nanodots on the trap dielectric layer.

21. The method of claim 20, wherein the nanodots are formed of a conductive material.

22. The method of claim 21, wherein the conductive material is Si, Ge or metal material.

23. The method of claim 22, further comprising, oxidizing the nanodots formed of the Si, Ge, or metal material.

24. The method of claim 20, wherein etching the trap dielectric layer comprises using the nanodots as an etch mask to form the dielectric nanoclusters.

25. The method of claim 20, wherein the gate pattern comprises the nanoclusters separated by the control gate dielectric layer, the nanodots located on the nanoclusters, the control gate dielectric layer and the control gate, which are sequentially stacked.

26. A semiconductor device comprising:
a semiconductor substrate;
a tunnel dielectric layer overlying the semiconductor substrate;
a plurality of dielectric nanoclusters overlying the tunnel dielectric layer;
a control gate dielectric layer overlying the plurality of dielectric nanoclusters;
a control gate overlying the control gate dielectric layer; and
a source/drain region formed in the semiconductor substrate and adjacent the control gate.

27. The semiconductor device of claim 26, further comprising a nanodot overlying corresponding one of the plurality of dielectric nanoclusters.

28. The semiconductor device of claim 26, wherein the plurality of dielectric nanoclusters are separated from each other by the control gate dielectric layer.
